(19) United States
(12) Patent Application Publication
(10) Pub. No.: US 2026/0005190 A1
(43) Pub. Date: Jan. 1, 2026

(54) Semiconductor Device and Method of Forming Interconnect Structure Using VFM and TCB

(71) Applicant: JCET STATS ChipPAC Korea Limited, Incheon (KR)

(72) Inventors: Minsung Lee, Incheon (KR); Yeojun Yun, Incheon (KR); HeeSoo Lee, Incheon (KR); Junhee Park, Incheon (KR)

(73) Assignee: JCET STATS ChipPAC Korea Limited, Incheon (KR)

(21) Appl. No.: 18/760,283

(22) Filed: Jul. 1, 2024

(51) Int. Cl. H01L 23/00; H01L 21/67; H01L 23/31; H01L 23/538; H01L 25/065

(52) U.S. Cl. CPC H01L 24/81; H01L 21/67103; H01L 24/16; H01L 24/13; H01L 24/75; H01L 24/94; H01L 24/97; H01L 2224/13111; H01L 2224/13113; H01L 2224/13116; H01L 2224/13124; H01L 2224/13139; H01L 2224/13144; H01L 2224/13147; H01L 2224/13155; H01L 2224/16145; H01L 2224/16225; H01L 2224/75253; H01L 2224/753; H01L 2224/81024; H01L 2224/81203; H01L 2224/8122; H01L 2224/94; H01L 2224/97

(57) ABSTRACT

A semiconductor device has a first substrate and a second substrate or interconnect substrate with an interconnect structure formed between the first substrate and second substrate or interconnect substrate using a VFM signal, in combination with heat and/or pressure. The interconnect structure can be a bump or a bump with conductive pillars. A microwave source disposed in proximity to the first and second substrates generates the VFM signal. Heat and pressure can be applied to the interconnect structure while using the VFM signal. Heat or pressure can be applied to the interconnect structure while using the VFM signal. A non-conductive film can be formed around the interconnect structure between the first substrate and second substrate. An epoxy and flux material can be formed around the interconnect structure between the first substrate and second substrate.

### FIELD OF THE INVENTION

The present invention relates in general to semiconductor devices and, more particularly, to a semiconductor device and method of forming an interconnect structure using VFM and TCB.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Multiple semiconductor wafers or individual semiconductor die can be stacked in a semiconductor package, commonly known as 3D integration. In particular, products such as integrating logic and memory circuits, sensor packaging, and combining micro electromechanical system (MEMS) use 3D integration to reduce the form factor, enhance performance, lower power consumption, increase integration capacity, and reduce costs.

The interconnect structure, e.g., bumps and conductive pillars, between stacked components in 3D integration is commonly done by thermal-compression bonding (TCB). TCB bonding uses heat and pressure to bond materials, typically thin films or layers. The heat softens the materials, and the pressure makes intimate contact between them, allowing bonds to form. However, if the heat and pressure are not uniformly transferred, potentially due to structural limitations, the interconnect structure can fail. Heat and pressure can become non-uniform, particularly for the interconnect structures furthest away from the heat source. A failure of the interconnect structure can cause the stacked wafer or die to tilt, slip, or warp, leading to defects and reduced reliability.

### BRIEF DESCRIPTION OF THE DRAWINGS

FIGS. 1a-1f illustrate a semiconductor wafer with a plurality of semiconductor die separated by a saw street;

FIGS. 2a-2m illustrate a process of bonding a semiconductor wafer to an interconnect substrate using VFM and TCB;

FIGS. 3a-3d illustrate another process of bonding a semiconductor wafer to an interconnect substrate using VFM and TCB;

FIGS. 4a-4d illustrate a process of bonding a first semiconductor wafer to a second semiconductor wafer using VFM and TCB;

FIGS. 5a-5c illustrate a process of bonding a plurality of stacked semiconductor wafers using VFM and TCB;

FIGS. 6a-6c illustrate another process of bonding a plurality of stacked semiconductor wafers using VFM and TCB;

FIGS. 7a-7g illustrate another process of bonding a plurality of electrical components to an interconnect substrate using VFM and TCB;

FIGS. 8a-8e illustrate another process of bonding a plurality of electrical components to a semiconductor wafer using VFM and TCB;

FIGS. 9a-9d illustrate another process of bonding an electrical component to an interconnect substrate using VFM and TCB;

FIGS. 10a-10d illustrate another process of bonding an electrical component to another electrical components using VFM and TCB;

FIGS. 11a-11c illustrate a process of bonding a plurality of stacked electrical components using VFM and TCB;

FIGS. 12a-12c illustrate another process of bonding a plurality of stacked electrical components using VFM and TCB;

FIG. 13 illustrates a non-conductive film deposited between the plurality of stacked semiconductor wafers;

FIG. 14 illustrates an epoxy material deposited around the interconnect structure between the plurality of stacked semiconductor wafers; and

FIG. 15 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

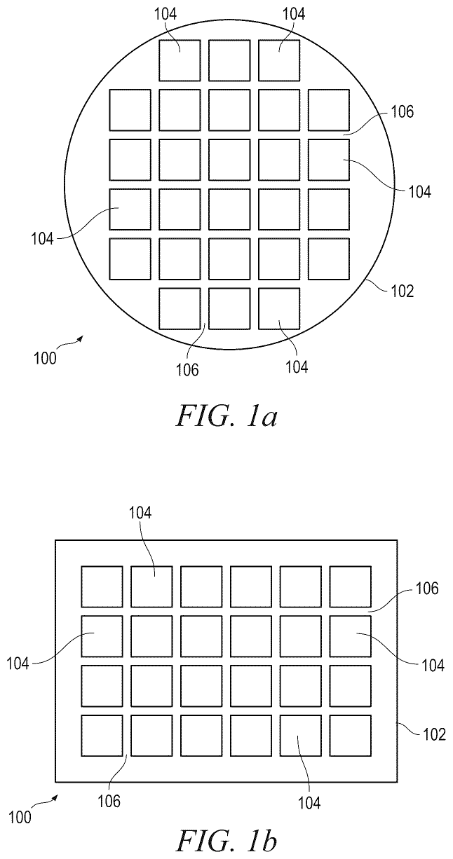

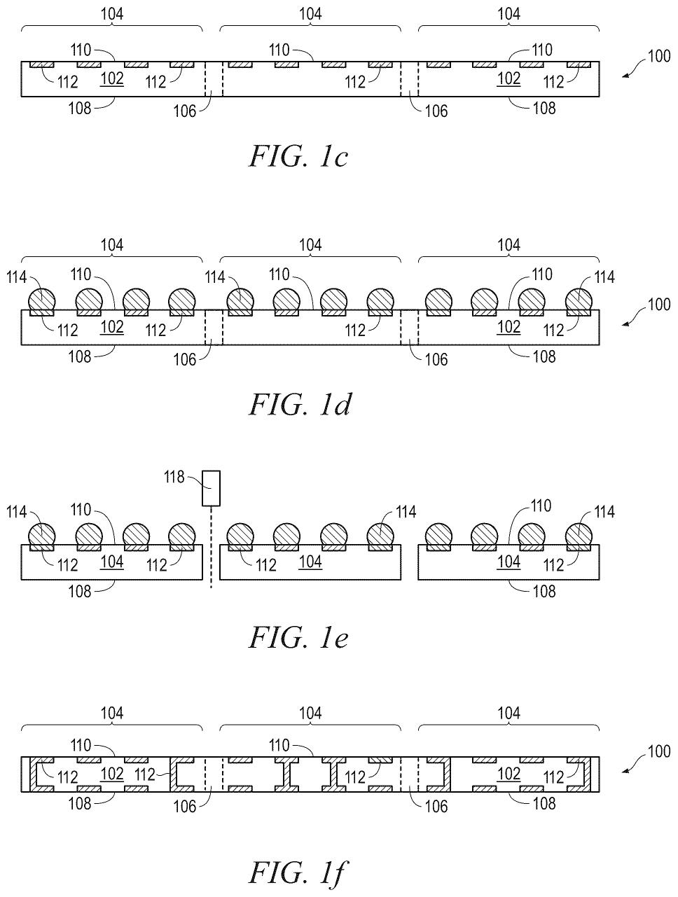

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 is circular with a diameter of 100-450 millimeters (mm). Semiconductor wafer 100 can be rectangular, as shown in FIG. 1b, or any other geometric shape.

FIG. 1c shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1d, an electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1e, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

In an alternate embodiment, conductive layer 112 may extend through base material 102 to surface 108, as shown in FIG. 1f. Semiconductor wafer 100 from FIG. 1f can be singulated as in FIG. 1e.

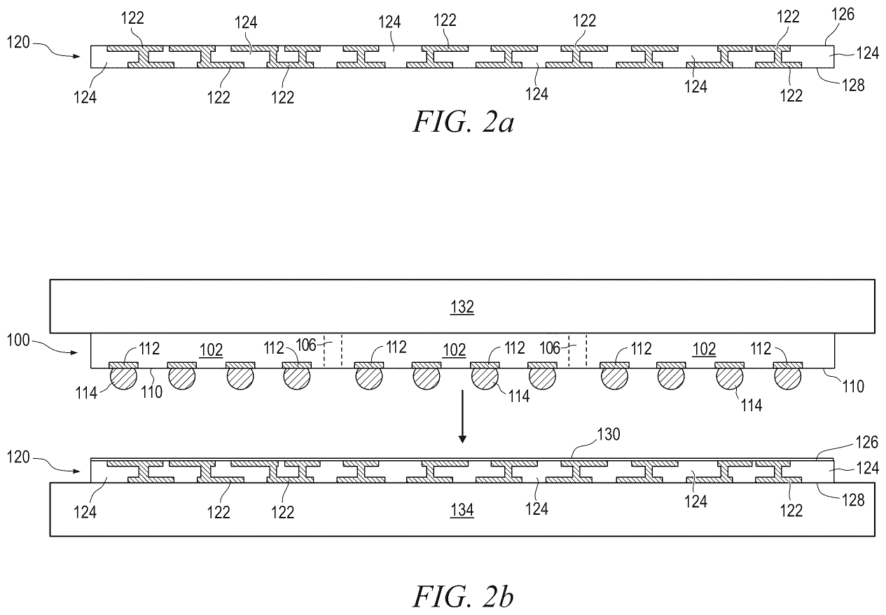

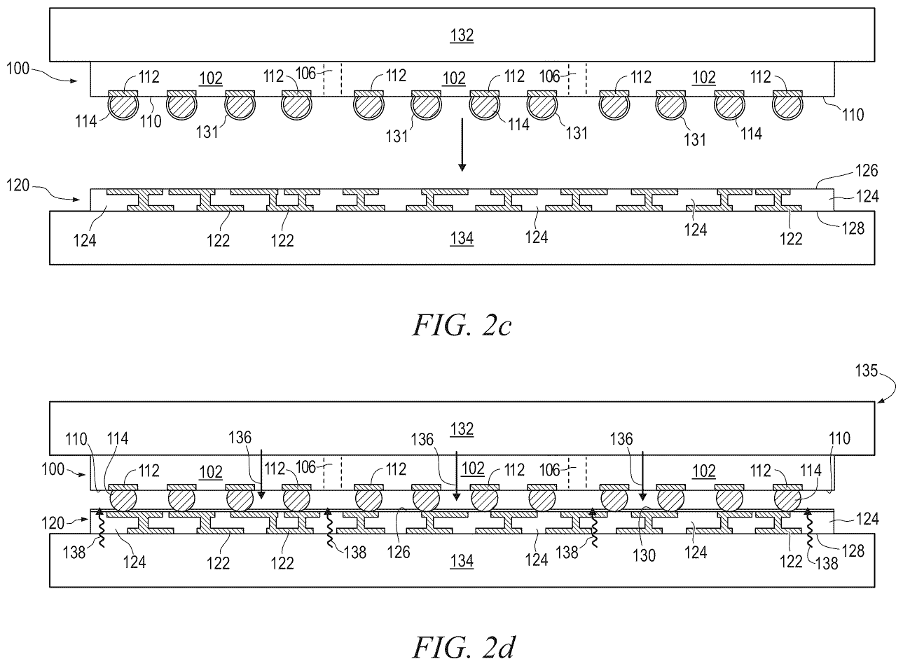

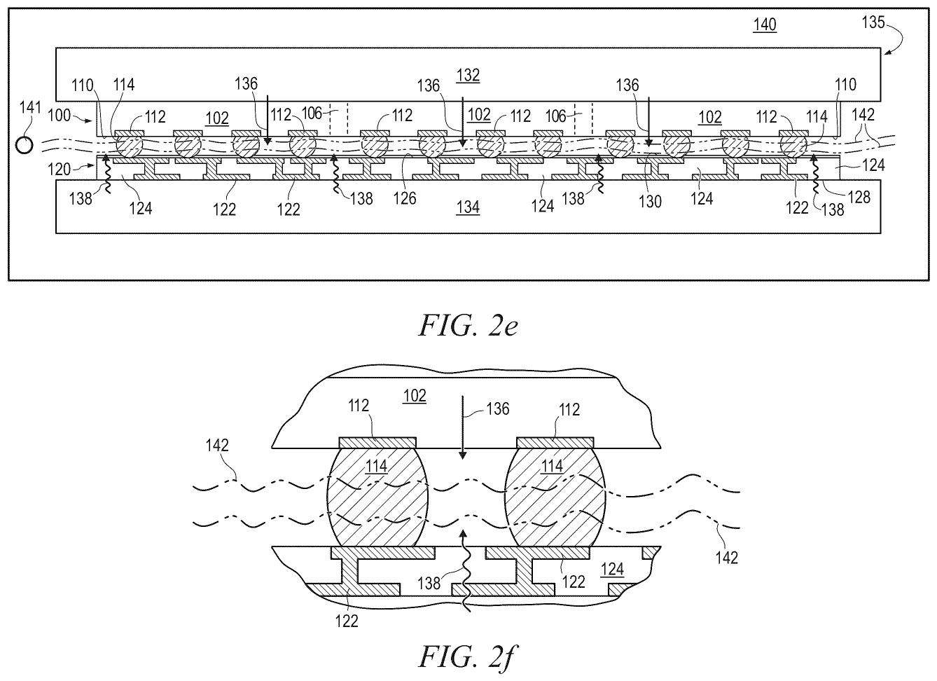

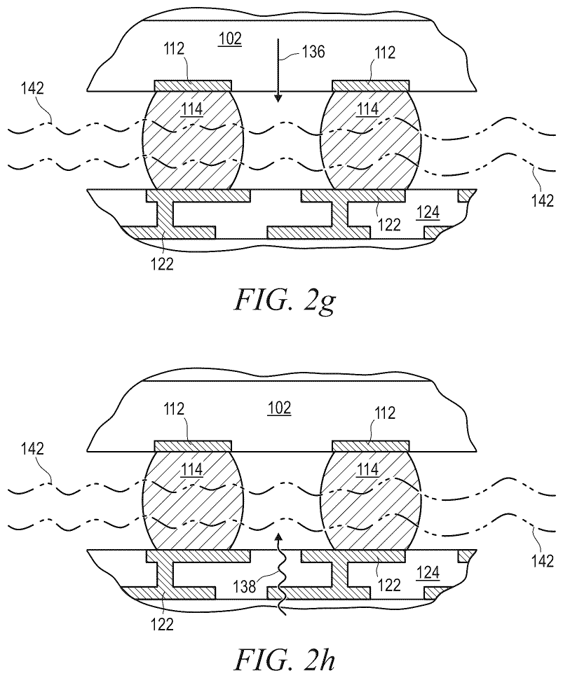

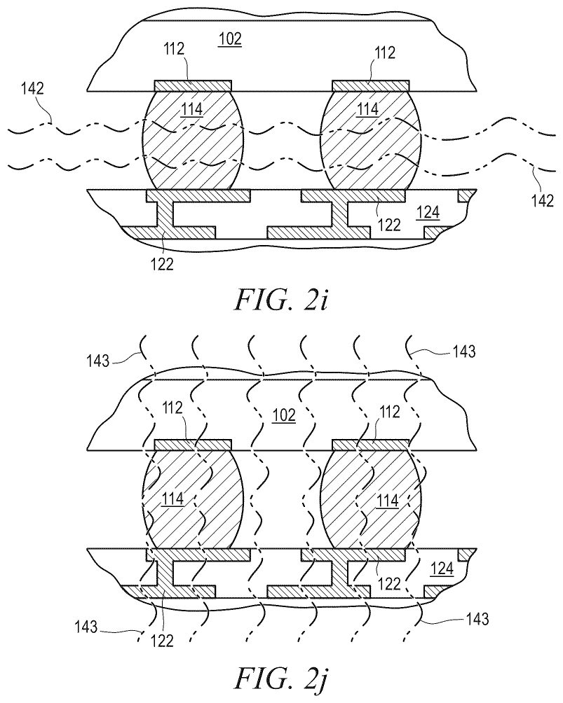

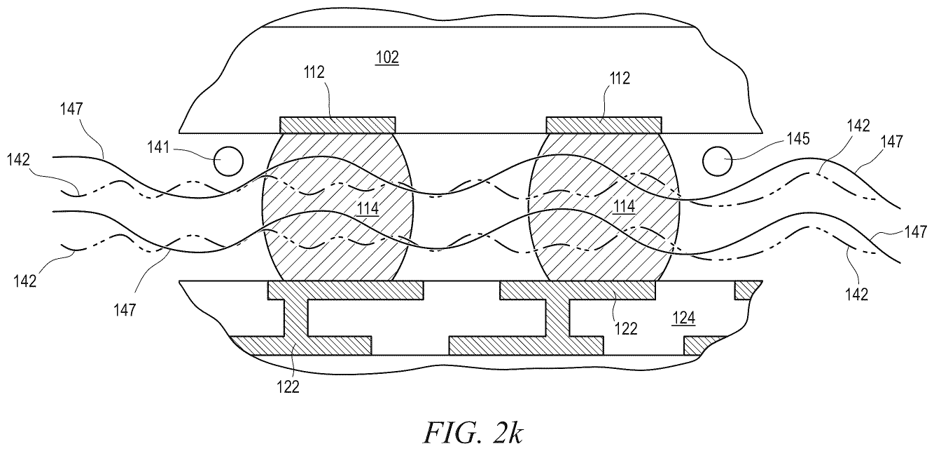

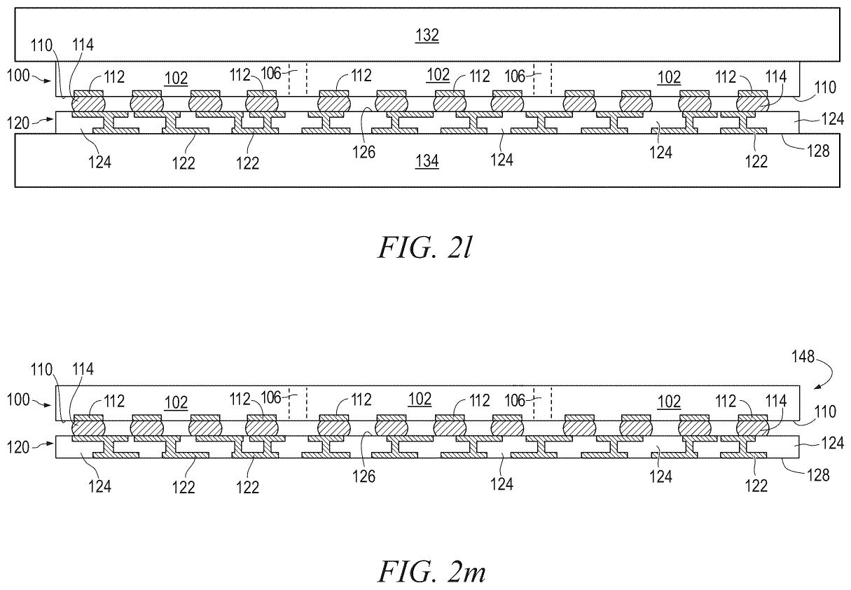

FIGS. 2a-2m illustrate a process of bonding a semiconductor wafer to an interconnect substrate using VFM and TCB. FIG. 2a shows a cross-sectional view of interconnect substrate or interposer 120 including one or more conductive layers 122 and one or more insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating process, or other suitable metal deposition process. Conductive layers 122 provide horizontal electrical interconnect across substrate 120 and vertical electrical interconnect between top surface 126 and bottom surface 128 of substrate 120. Portions of conductive layers 122 can be electrically common or electrically isolated depending on the design and function of semiconductor die 104 and other electrical components. Insulating layers 124 contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layers 124 can be formed using PVD, CVD, printing, lamination, spin coating, spray coating, sintering or thermal oxidation. Insulating layers 124 provide isolation between conductive layers 122. There can be multiple conductive layers like 122 separated by insulating layers 124.

In FIG. 2b, semiconductor wafer 100 from FIG. 1d is disposed over surface 126 of interconnect substrate 120 using a pick and place operation. As referenced herein, semiconductor wafer 100 can be a first substrate and interconnect substrate 120 can be a second substrate. Also as referenced herein, semiconductor wafer 100 can be a first electrical component and interconnect substrate 120 can be a second electrical component. A flux material 130 is deposited on surface 126. Alternatively, flux 131 is deposited over bumps 114, as in FIG. 2c. Semiconductor wafer 100 is attached to thermal-compression block 132, and interconnect substrate 120 is attached to thermal block 134. Thermal-compression block 132 applies heat and pressure to semiconductor wafer 100. Thermal block 134 applies heat to interconnect substrate 120. Semiconductor wafer 100 and interconnect substrate 120 are preheated by thermal-compression block 132 and thermal block 134, respectively. The preheat activates bumps 114, as well as conductive layers 112 and 122.

In FIG. 2d, semiconductor wafer 100 is aligned with and brought into contact with surface 126 of substrate 120, represented as bonding assembly 135. The electrical and mechanical bonding process of bumps 114 to conductive layers 112 and 122 utilizes potentially three simultaneous operations. Thermal-compression block 132 applies heat and pressure to semiconductor wafer 100 to heat and compress bumps 114, represented by indicator arrow 136. Thermal block 134 applies heat to interconnect substrate 120 to provide additional heat, represented by indicator arrow 138.

It is important the heat and pressure remain uniform, with minimal stress, across bumps 114 to maximize or at least enhance the molecular and atomic bonding between bumps 114 and conductive layers 112 and 122. Toward that end, bonding assembly 135 is disposed within microwave source 140 to transmit variable frequency microwave (VFM) signal 142 to bumps 114 and conductive layers 112 and 122, as shown in FIG. 2e. Microwave source 140 includes magnetron 141 to generate and emit VFM signal 142. In one embodiment, microwave source 140 can be a microwave oven capable of emitting heat-generating microwaves. In another embodiment, microwave source 140 is disposed on opposite sides of bonding assembly 135. Microwave source 140 can be disposed on one side of bonding assembly 135, or above or below bonding assembly 135.

Microwave source 140 emits VFM signals 142 toward bumps 114 and conductive layers 112 and 122. FIG. 2f shows further detail of heat-pressure indicator 136, heat indicator 138, and VFM signals 142 around bumps 114 and conductive layers 112 and 122. Heat-pressure indicator 136 works to conform the materials to each other and accommodate any asperities or surface. The combination of heat and pressure facilitates atomic or molecular diffusion across the interface, forming a strong bond. In the case of solder or adhesive layers, the heat causes these layers to melt and flow, filling gaps and creating a solid joint upon cooling. Heat indicator 138 provides uniform heating, i.e., from an opposing direction, and precise temperature control.

VFM signals 142 from microwave source 140 include electromagnetic radiation in the frequency range of 300 MHz to 300 GHZ. In one embodiment, the frequency range is 4.0 GHZ-8.0 GHz, or preferably 5.7 GHZ-7.0 GHz. VFM signals 142 change frequency in 25 milliseconds (ms) intervals to achieve the desired uniform thermal-pressure energy distribution. More specifically, VFM signals 142 cause molecules to rotate without breaking their bonds. The electric field causes the electron cloud around positive atomic nuclei to distort in the direction opposite to the field. Molecules with electrons then rotate following the electric field direction. As these rotating molecules collide with neighboring molecules, the energy from these collisions is converted into heat energy through friction. Flux 130, being a polar material, can be heated by VFM signal 142. Likewise, bump 114 is heated and melted by VFM signal 142. The temperature of flux 130 rises over bump melting temperature and effectively dissolves and mixes with the melted bump material. Notably, semiconductor wafer 100 and interconnect substrate 120 are not polar material and remain unaffected by VFM signal 142. As a result, the temperature level becomes uniform across bumps 114 and conductive layers 112 and 122, typically with no metal arcing between the bumps and conductive layers. VFM signals 142 make the formation of bonds between bumps 114 and conductive layers 112 and 122, in the presence of heat and/or pressure, more efficient and uniform.

FIG. 2g illustrates another embodiment of VFM signals 142 with heat-pressure indicator 136, but without heat indicator 138. In this embodiment, thermal-compression block 132 and VFM signals 142 are the sources of heat and pressure to bond bumps 114 to conductive layers 112 and 122.

FIG. 2h illustrates another embodiment of VFM signals 142 with heat indicator 138, but without heat-pressure indicator 136. In this embodiment, thermal block 134 and VFM signals 142 are the sources of heat to bond bumps 114 to conductive layers 112 and 122.

FIG. 2i illustrates another embodiment of VFM signals 142, without heat-pressure indicator 136 and without heat indicator 138. In this embodiment, VFM signals 142 is the horizontal source of heat to bond bumps 114 to conductive layers 112 and 122. Heat-pressure indicator 136 and heat indicator 138 are used to preheat bonding assembly 135.

FIG. 2j illustrates another embodiment of VFM signals 143, without heat-pressure indicator 136 and without heat indicator 138. In this embodiment, VFM signals 143 is the vertical source of heat to bond bumps 114 to conductive layers 112 and 122. Heat-pressure indicator 136 and heat indicator 138 are used to preheat bonding assembly 135.

FIG. 2k illustrates another embodiment of VFM signals, without heat-pressure indicator 136 and without heat indicator 138. In this embodiment, magnetron 141 generates VFM signals 142 and magnetron 145 generates VFM signals 147 of different frequency and/or out-of-phase with respect to VFM signals 142. VFM signals 142 and 147 are the sources of heat to bond bumps 114 to conductive layers 112 and 122. Heat-pressure indicator 136 and heat indicator 138 are used to preheat bonding assembly 135.

In any case, FIG. 2l shows semiconductor wafer 100 bonded to interconnect substrate 120, as semiconductor package 148, with bumps 114 electrically and mechanically connected between conductive layers 112 and 122 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution. FIG. 2m shows semiconductor package 148, outside bonding assembly 135, with bumps 114 electrically and mechanically connected between conductive layers 112 and 122.

The combination of semiconductor wafers 100 and interconnect substrate 120 represent semiconductor package 148. Semiconductor wafer 100 and interconnect substrate 120 have improved interconnect bonding with bumps 114 electrically and mechanically connected between conductive layers 112 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background. The heat-generating VFM signal 142 does not heat semiconductor wafer 100 nor interconnect substrate 120 so these structures do not warp. The volumetric heating characteristic enables efficient control of heat distribution.

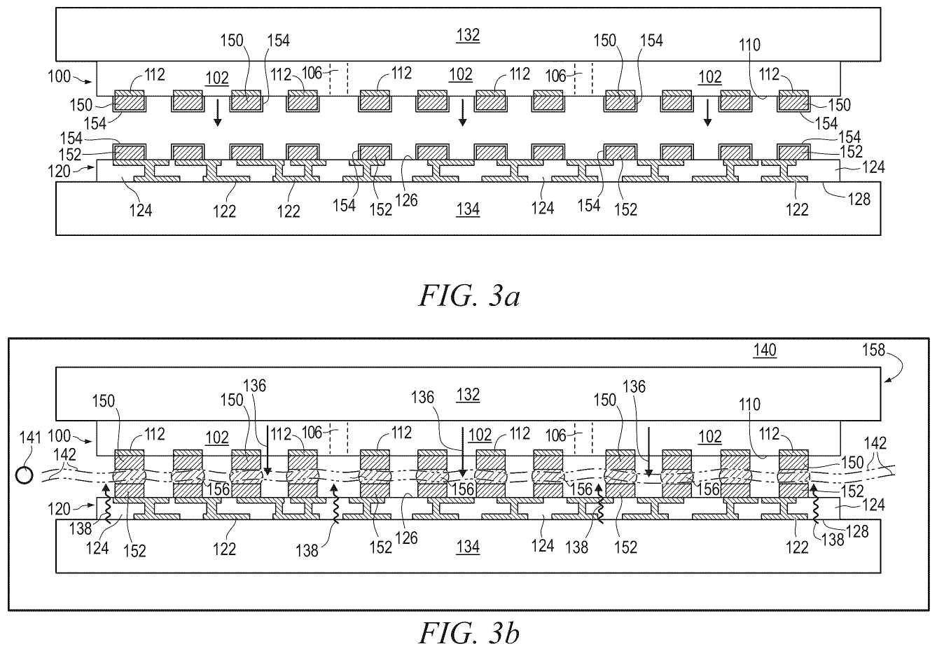

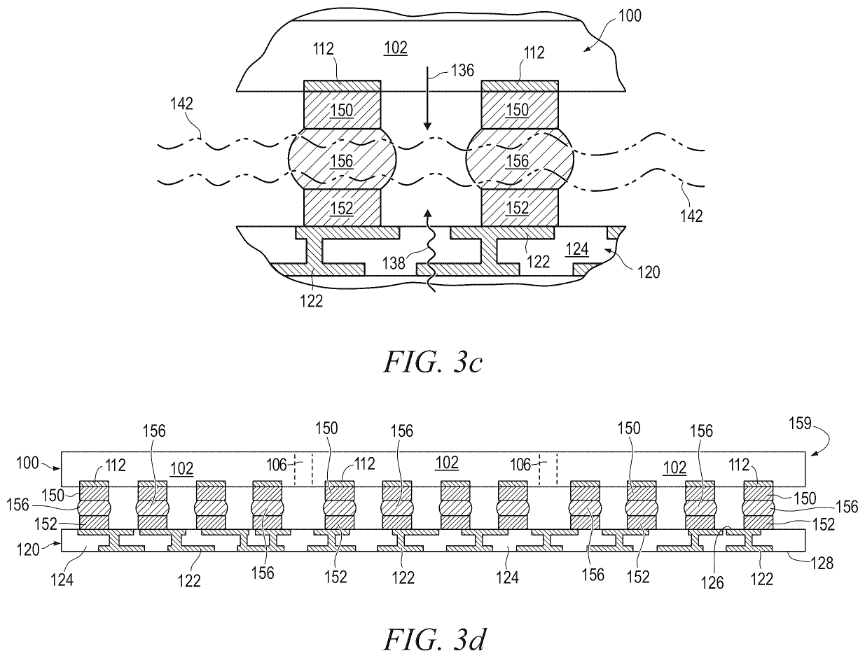

In another embodiment, semiconductor wafer 100 from FIG. 1c is disposed over surface 126 of interconnect substrate 120 using a pick and place operation, as shown in FIG. 3a. Components having a similar function are assigned the same reference number. A plurality of electrically conductive pillars or pedestals 150 is formed over conductive layer 112. Likewise, a plurality of electrically conductive pillars or pedestals 152 is formed over conductive layer 122. Conductive pillars 150 and 152 can be formed with a photoresist layer deposited over semiconductor wafer 100 and interconnect substrate 120, respectively. The photoresist layer is patterned and etched according to the intended locations of conductive pillars 150 and 152. The openings in the photoresist layer are filled with electrically conductive material, such as Al, Cu, Sn, Ni, Au, Ag, or other suitable electrically conductive material, to form conductive pillars 150 and 152. A flux material 154 is deposited on conductive pillars 150 and 152.

Semiconductor wafer 100 from FIG. 1c is attached to thermal-compression block 132, and interconnect substrate 120 is attached to thermal block 134. Thermal-compression block 132 applies heat and pressure to semiconductor wafer 100. Thermal block 134 applies heat to interconnect substrate 120. Semiconductor wafer 100 and interconnect substrate 120 are preheated by thermal-compression block 132 and thermal block 134, respectively. The preheat activates conductive pillars 150 and 152, as well as conductive layers 112 and 122.

In FIG. 3b, semiconductor wafer 100 is aligned with and brought toward interconnect substrate 120 with intermediate bumps 156 contacting conductive pillars 150 and 152, represented as bonding assembly 158. The electrical and mechanical bonding process of bumps 156 to conductive pillars 150 and 152 utilizes potentially three simultaneous operations. Thermal-compression block 132 applies heat and pressure to semiconductor wafer 100 to heat and compress bumps 156, represented by indicator arrow 136. Thermal block 134 applies heat to interconnect substrate 120 to provide additional heat, represented by indicator arrow 138.

It is important the heat and pressure remain uniform, with minimal stress, across bumps 156 to maximize or at least enhance the molecular and atomic bonding between bumps 156 and conductive pillars 150 and 152. Toward that end, bonding assembly 158 is disposed within microwave source 140 to transmit VFM signal 142 to bumps 156 and conductive pillars 150 and 152. FIG. 3c shows further detail of heat-pressure indicator 136, heat indicator 138, and VFM signals 142 around bumps 156 and conductive pillars 150 and 152, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 3d shows semiconductor wafer 100 bonded to interconnect substrate 120, as semiconductor package 159, with bumps 156 electrically and mechanically connected between conductive pillars 150 and 152 using a combination of thermal-compression block 132, thermal block 134, and microwave source 140, or microwave source 140 with either thermal-compression block 132 or thermal block 134, or microwave source 140 without heat-pressure indicator 136 and without heat indicator 138, to achieve a uniform heat-pressure distribution.

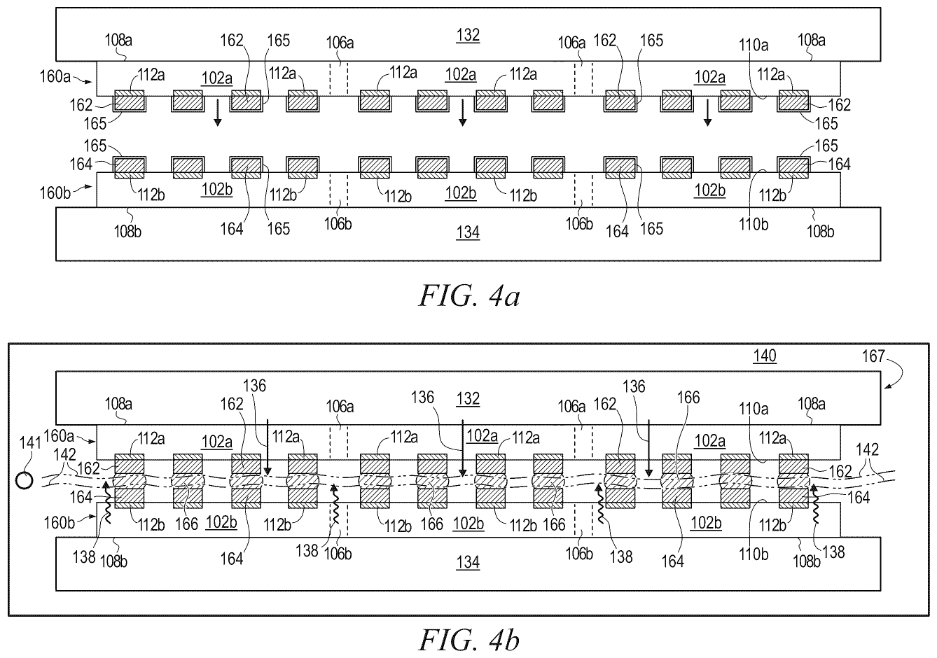

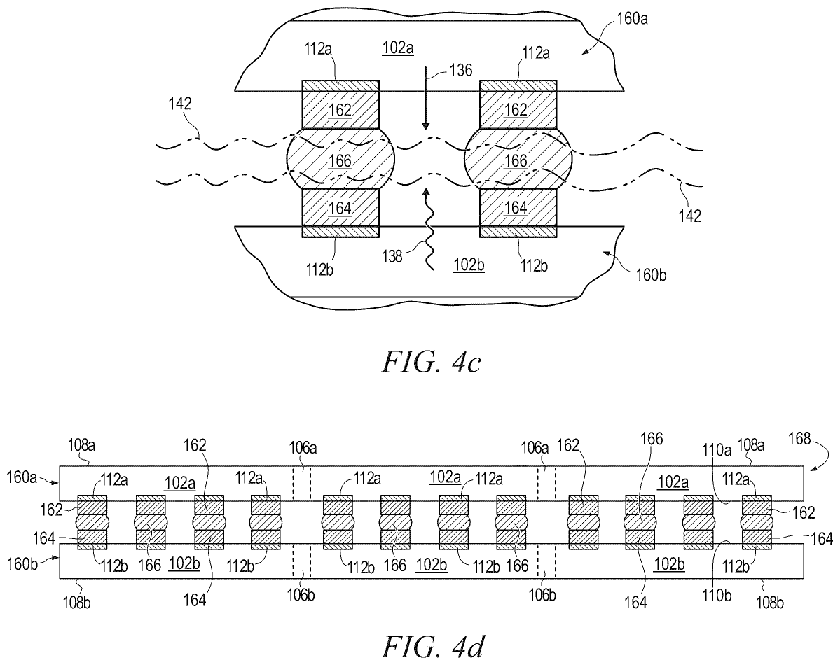

In another embodiment, semiconductor wafer 160a is disposed over semiconductor wafer 160b using a pick and place operation, as shown in FIG. 4a. Semiconductor wafer 160a is made similar to semiconductor wafer 100 from FIG. 1c. Semiconductor wafer 160b is also made similar to semiconductor wafer 100 from FIG. 1c. As referenced herein, semiconductor wafer 160a can be a first substrate and semiconductor wafer 160b can be a second substrate. Also as referenced herein, semiconductor wafer 160a can be a first electrical component and semiconductor wafer 160b can be a second electrical component.

A plurality of electrically conductive pillars or pedestals 162 is formed over conductive layer 112a. Likewise, a plurality of electrically conductive pillars or pedestals 164 is formed over conductive layer 112b. Conductive pillars 162 and 164 can be formed with a photoresist layer deposited over semiconductor wafer 160a and semiconductor wafer 160b, respectively. The photoresist layer is patterned and etched according to the intended locations of conductive pillars 162 and 164. The openings in the photoresist layer are filled with electrically conductive material, such as Al, Cu, Sn, Ni, Au, Ag, or other suitable electrically conductive material, to form conductive pillars 162 and 164. A flux material 165 is deposited on conductive pillars 162 and 164.

Semiconductor wafer 160a is attached to thermal-compression block 132, and semiconductor wafer 160b is attached to thermal block 134. Thermal-compression block 132 applies heat and pressure to semiconductor wafer 160a. Thermal block 134 applies heat to semiconductor wafer 160b. Semiconductor wafer 160a and semiconductor wafer 160b are preheated by thermal-compression block 132 and thermal block 134, respectively. The preheat activates conductive pillars 162 and 164, as well as conductive layers 112a and 112b.

In FIG. 4b, semiconductor wafer 160a is aligned with and brought toward semiconductor wafer 160b with intermediate bumps 166 contacting conductive pillars 162 and 164, represented as bonding assembly 167. The electrical and mechanical bonding process of bumps 166 to conductive pillars 162 and 164 utilizes potentially three simultaneous operations. Thermal-compression block 132 applies heat and pressure to semiconductor wafer 160a to heat and compress, bumps 166, represented by indicator arrow 136. Thermal block 134 applies heat to semiconductor wafer 160b to provide additional heat, represented by indicator arrow 138.

It is important the heat and pressure remain uniform, with minimal stress, across bumps 166 to maximize or at least enhance the molecular and atomic bonding between bumps 166 and conductive pillars 162 and 164. Toward that end, bonding assembly 167 is disposed within microwave source 140 to transmit VFM signal 142 to bumps 166 and conductive pillars 162 and 164. FIG. 4c shows further detail of heat-pressure indicator 136, heat indicator 138, and VFM signals 142 around bumps 166 and conductive pillars 162 and 164, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 4d shows semiconductor wafer 160a bonded to semiconductor wafer 160b, as semiconductor package 168, with bumps 166 electrically and mechanically connected between conductive pillars 162 and 164 using a combination of thermal-compression block 132, thermal block 134, and microwave source 140, or microwave source 140 with either thermal-compression block 132 or thermal block 134, or microwave source 140 without heat-pressure indicator 136 and without heat indicator 138, to achieve a uniform heat-pressure distribution.

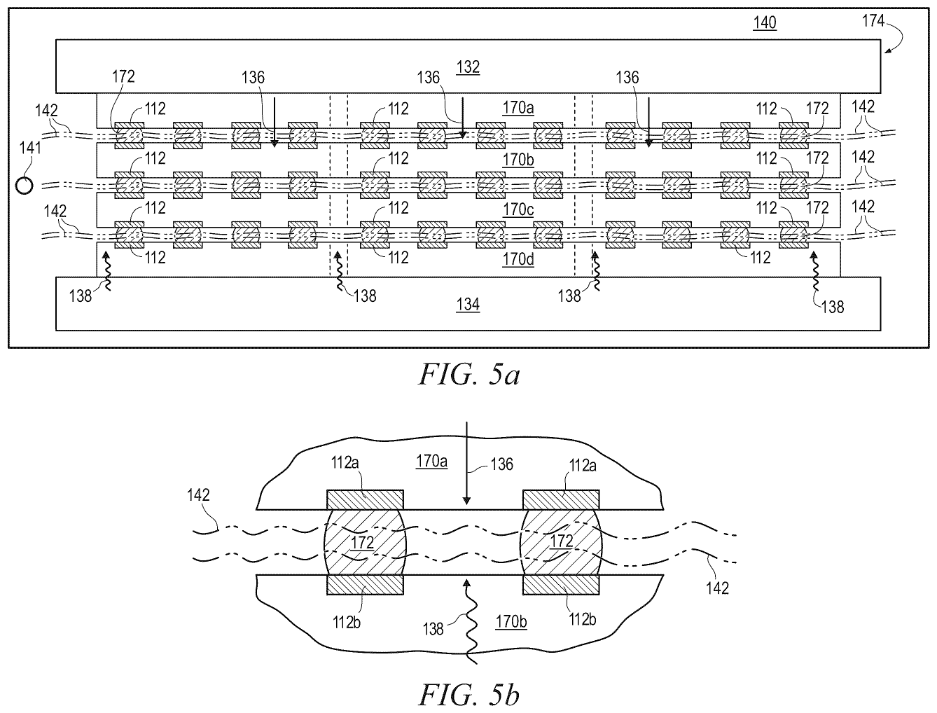

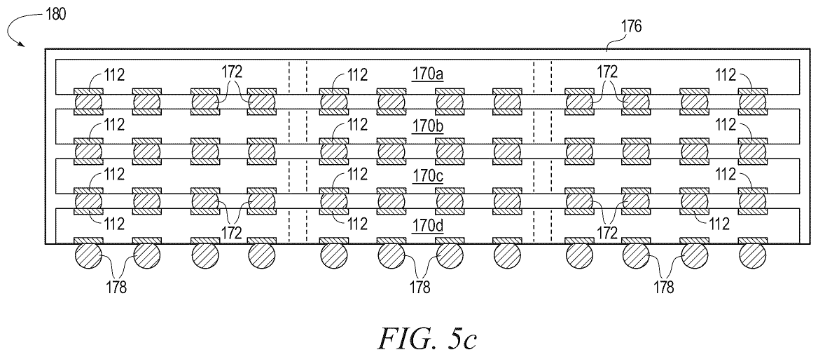

In another embodiment of stacking multiple semiconductor wafers, semiconductor wafer 170a is aligned with and disposed over semiconductor wafer 170b, semiconductor wafer 170b is aligned with and disposed over semiconductor wafer 170c, and semiconductor wafer 170c is aligned with and disposed over semiconductor wafer 170d using a pick and place operation, as shown in FIG. 5a. Semiconductor wafers 170a, 170b, 170c, and 170d are each made similar to semiconductor wafer 100 from FIG. 1f. Any number of semiconductor wafers 170 can be stacked as shown. For example, four to twelve semiconductor wafers 170 can be stacked. As referenced herein, one of semiconductor wafers 170a-170d can be a first substrate and one of semiconductor wafers 170a-170d can be a second substrate. Also as referenced herein, one of semiconductor wafers 170a-170d can be a first electrical component and one of semiconductor wafers 170a-170d can be a second electrical component.

A plurality of bumps 172 is disposed between semiconductor wafers 170a and 170b, and between semiconductor wafers 170b and 170c, and between semiconductor wafers 170c and 170d, over conductive layers like 112. A flux material is deposited on bumps 172, similar to FIG. 2c.

Semiconductor wafer 170a is attached to thermal-compression block 132, and semiconductor wafer 170d is attached to thermal block 134. Thermal-compression block 132 applies heat and pressure to semiconductor wafer 170a-170d. Thermal block 134 applies heat to semiconductor wafer 170a-170d. Semiconductor wafers 170a-170d are preheated by thermal-compression block 132 and thermal block 134.

Semiconductor wafers 170a-170d are disposed between thermal-compression block 132 and thermal block 134 and bumps 172 contacting conductive layer 112, represented as bonding assembly 174. The electrical and mechanical bonding process of bumps 172 to conductive layers 112 utilizes potentially three simultaneous operations. Thermal-compression block 132 applies heat and pressure to semiconductor wafers 170a-170d to heat and compress bumps 172, represented by indicator arrow 136. Thermal block 134 applies heat to semiconductor wafers 170a-170d to provide additional heat, represented by indicator arrow 138.

It is important the heat and pressure remain uniform, with minimal stress, across bumps 172 to maximize or at least enhance the molecular and atomic bonding between bumps 172 and conductive layers 112. Toward that end, bonding assembly 174 is disposed within microwave source 140 to transmit VFM signal 142 to bumps 172 and conductive layers 112. FIG. 5b shows further detail of heat-pressure indicator 136, heat indicator 138, and VFM signals 142 around bumps 166 and conductive pillars 162 and 164, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 5c shows bonded semiconductor wafers 170a-170d with bumps 172 electrically and mechanically connected between conductive layers 112 using a combination of thermal-compression block 132, thermal block 134, and microwave source 140, or microwave source 140 with either thermal-compression block 132 or thermal block 134, or microwave source 140 without heat-pressure indicator 136 and without heat indicator 138, to achieve a uniform heat-pressure distribution.

An encapsulant or molding compound 176 is deposited over and around semiconductor wafers 170a-170d using a paste printing, compressive molding, transfer molding, liquid encapsulant molding, vacuum lamination, spin coating, or other suitable applicator. Encapsulant 176 can be polymer composite material, such as epoxy resin with filler, epoxy acrylate with filler, or polymer with proper filler. Encapsulant 176 is non-conductive, provides structural support, and environmentally protects the semiconductor device from external elements and contaminants.

An electrically conductive bump material is deposited over conductive layer 112 of semiconductor wafer 170d using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 178. In one embodiment, bump 178 is formed over a UBM having a wetting layer, barrier layer, and adhesive layer. Bump 178 can also be compression bonded or thermocompression bonded to conductive layer 112. Bump 178 represents one type of interconnect structure that can be formed over conductive layer 112. The interconnect structure can also use bond wires, conductive paste, stud bump, micro bump, or other electrical interconnect.

The combination of stacked semiconductor wafers 170a-170d with encapsulant 176 and bumps 178 represent semiconductor package 180. Semiconductor package 180 is particularly useful for high bandwidth memory (HBM). Stacked semiconductor wafer 170a-170d have improved interconnect bonding with bumps 172 electrically and mechanically connected between conductive layers 112 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background. The heat-generating VFM signal 142 does not heat semiconductor wafer 100 nor interconnect substrate 120 so these structures do not melt. The volumetric heating characteristic enables efficient control of heat distribution.

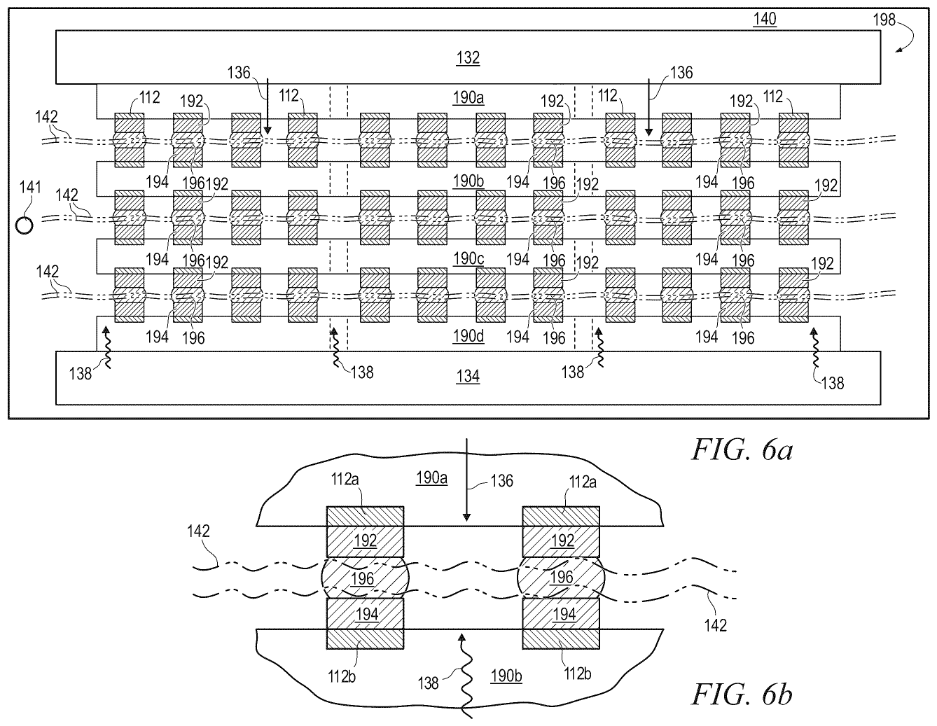

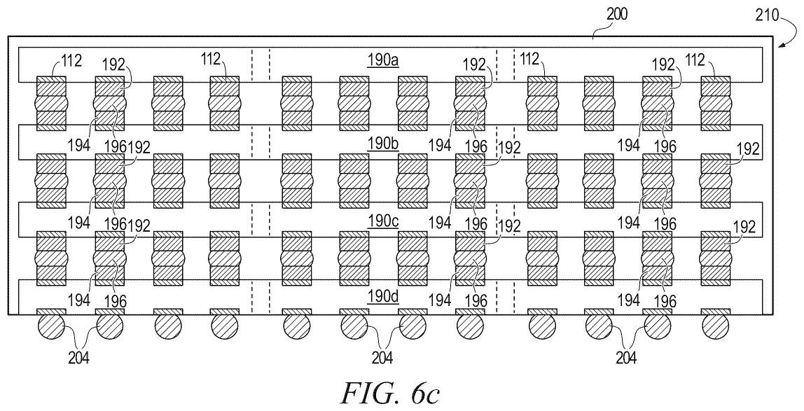

In another embodiment of stacking multiple semiconductor wafers, semiconductor wafer 190a is disposed over semiconductor wafer 190b, semiconductor wafer 190b is disposed over semiconductor wafer 190c, and semiconductor wafer 190c is disposed over semiconductor wafer 190d using a pick and place operation, as shown in FIG. 6a. Semiconductor wafers 190a, 190b, 190c, and 190d are each made similar to semiconductor wafer 100 from FIG. 1f. Any number of semiconductor wafers 190 can be stacked as shown. For example, four to twelve semiconductor wafers 170 can be stacked. As referenced herein, one of semiconductor wafers 190a-190d can be a first substrate and one of semiconductor wafers 190a-190d can be a second substrate. Also as referenced herein, one of semiconductor wafers 190a-190d can be a first electrical component and one of semiconductor wafers 190a-190d can be a second electrical component.

A plurality of electrically conductive pillars or pedestals 192 is formed over conductive layer 112 of semiconductor wafer 190a. Likewise, a plurality of electrically conductive pillars or pedestals 194 is formed over conductive layer 112 of semiconductor wafer 190b. Conductive pillars 192 and 194 can be formed with a photoresist layer deposited over semiconductor wafer 190a and semiconductor wafer 190b, respectively. The photoresist layer is patterned and etched according to the intended locations of conductive pillars 192 and 194. The openings in the photoresist layer are filled with electrically conductive material, such as Al, Cu, Sn, Ni, Au, Ag, or other suitable electrically conductive material, to form conductive pillars 192 and 194. A flux material is deposited on conductive pillars 192 and 194, similar to FIG. 4a.

Semiconductor wafer 190a is attached to thermal-compression block 132, and semiconductor wafer 190d is attached to thermal block 134. Thermal-compression block 132 applies heat and pressure to semiconductor wafer 190a-190d. Thermal block 134 applies heat to semiconductor wafer 190a-190d. Semiconductor wafers 190a-190d are preheated by thermal-compression block 132 and thermal block 134.

Semiconductor wafers 190a-190d disposed between thermal-compression block 132 and thermal block 134 and bumps 196 contacting conductive layer 112 represent as bonding assembly 198. The electrical and mechanical bonding process of bumps 196 to conductive layers 112 utilizes potentially three simultaneous operations. Thermal-compression block 132 applies heat and pressure to semiconductor wafers 190a-190d to heat and compress bumps 196, represented by indicator arrow 136. Thermal block 134 applies heat to semiconductor wafers 190a-190d to provide additional heat, represented by indicator arrow 138.

It is important the heat and pressure from thermal-compression block 132 and thermal block 134 remain uniform, with minimal stress, across bumps 196 to maximize or at least enhance the molecular and atomic bonding between bumps 196 and conductive pillars 192 and 194. Toward that end, bonding assembly 198 is disposed within microwave source 140 to transmit VFM signal 142 to bumps 196 and conductive pillars 192 and 194. FIG. 6b shows further detail of heat-pressure indicator 136, heat indicator 138, and VFM signals 142 around bumps 196 and conductive pillars 192 and 194, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 6c shows bonded semiconductor wafers 190a-190d with bumps 196 electrically and mechanically connected between conductive pillars 192 and 194 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution.

An encapsulant or molding compound 200 is deposited over and around semiconductor wafers 190a-190d using a paste printing, compressive molding, transfer molding, liquid encapsulant molding, vacuum lamination, spin coating, or other suitable applicator. Encapsulant 200 can be polymer composite material, such as epoxy resin with filler, epoxy acrylate with filler, or polymer with proper filler. Encapsulant 200 is non-conductive, provides structural support, and environmentally protects the semiconductor device from external elements and contaminants.

An electrically conductive bump material is deposited over conductive layer 112 of semiconductor wafer 190d using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 204. In one embodiment, bump 204 is formed over a UBM having a wetting layer, barrier layer, and adhesive layer. Bump 204 can also be compression bonded or thermocompression bonded to conductive layer 112. Bump 204 represents one type of interconnect structure that can be formed over conductive layer 112. The interconnect structure can also use bond wires, conductive paste, stud bump, micro bump, or other electrical interconnect.

The combination of stacked semiconductor wafers 190a-190d with encapsulant 200 and bumps 204 represent semiconductor package 210. Semiconductor package 210 is particularly useful for HBM. Stacked semiconductor wafer 190a-190d have improved interconnect bonding with bumps 196 electrically and mechanically connected between conductive pillars 192 and 194 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background.

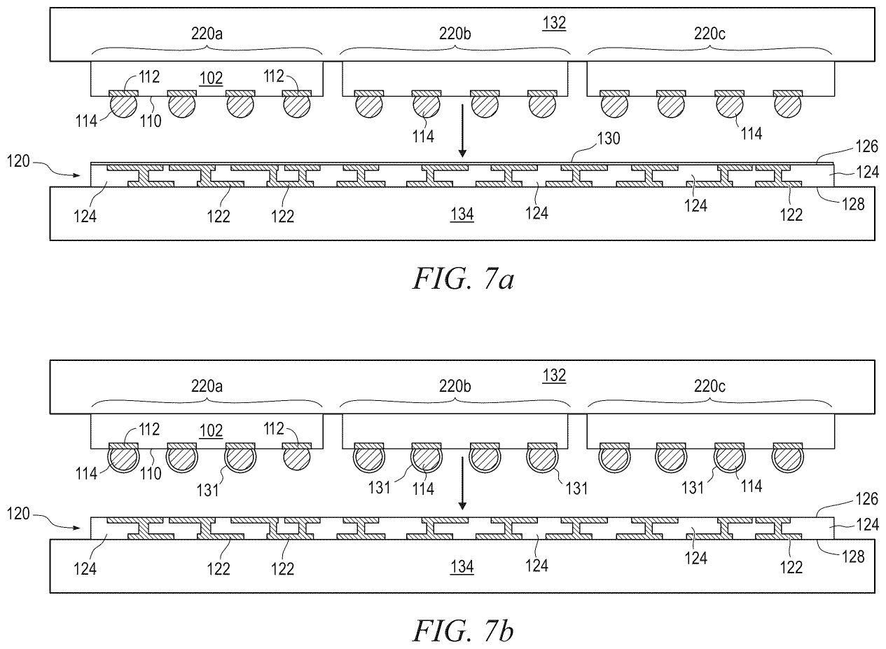

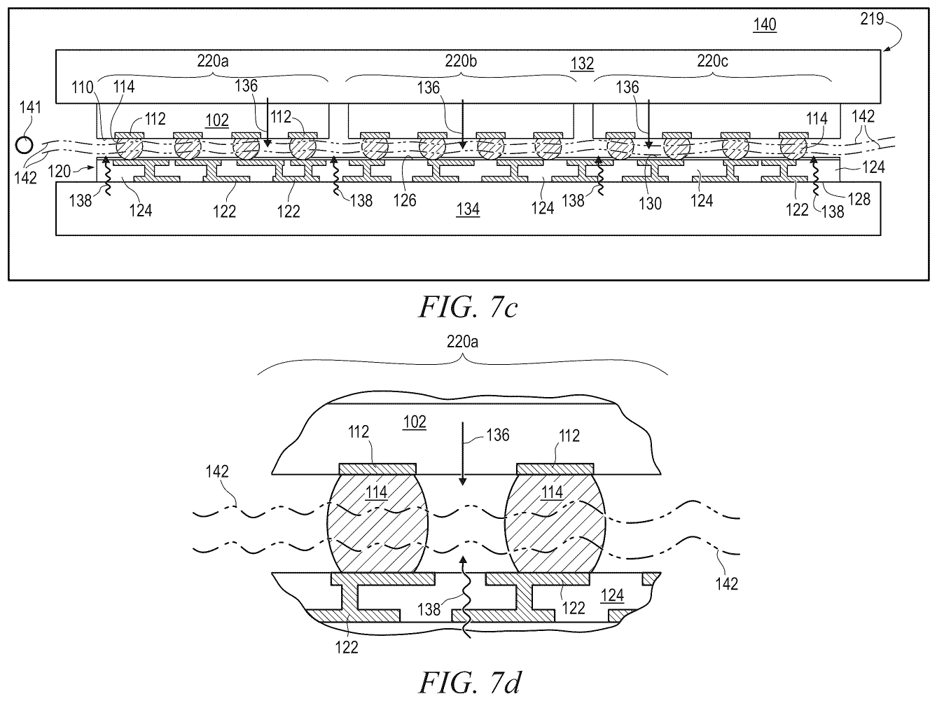

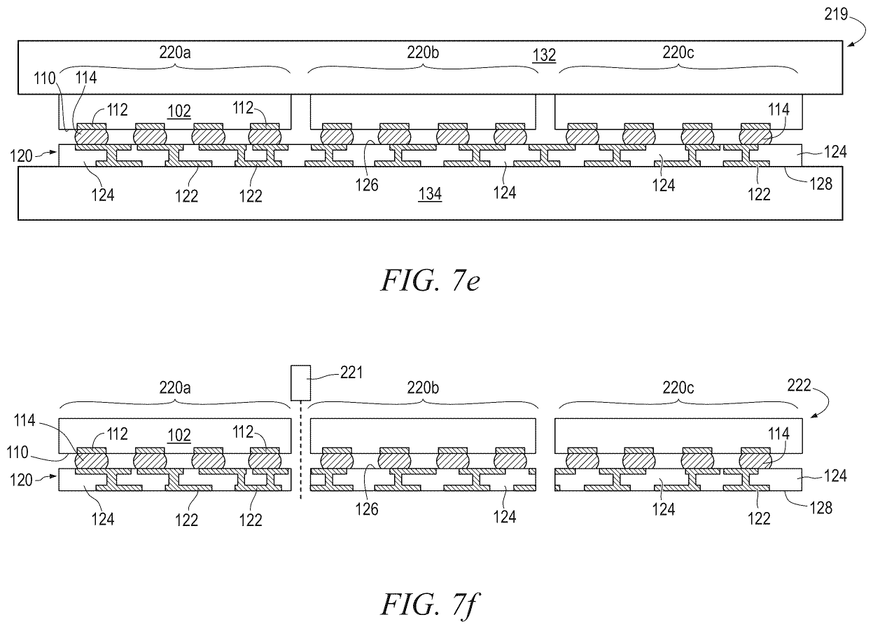

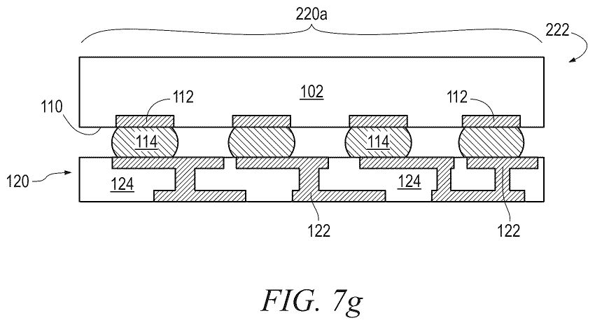

In another embodiment, a plurality of electrical components 220a-220c is disposed over surface 126 of interconnect substrate 120 using a pick and place operation, as shown in FIG. 7a. In one embodiment, electrical components 220a-220c can be made similar to semiconductor die 104 from FIG. 1e. Alternatively, electrical components 220a-220c can include other semiconductor die, semiconductor packages, surface mount devices, discrete electrical devices, interconnect structures, or IPDs. As referenced herein, any one of electrical components 220a-220c can be a first substrate and interconnect substrate 120 can be a second substrate. Also as referenced herein, any one of electrical components 220a-220c can be a first electrical component and interconnect substrate 120 can be a second electrical component. A flux material 130 is deposited on surface 126. Alternatively, flux 131 is deposited over bumps 114, as in FIG. 7b. Electrical components 220a-220c are attached to thermal-compression block 132, and interconnect substrate 120 is attached to thermal block 134. Thermal-compression block 132 applies heat and pressure to electrical components 220a-220c. Thermal block 134 applies heat to interconnect substrate 120. Electrical components 220a-220c and interconnect substrate 120 are preheated by thermal-compression block 132 and thermal block 134, respectively. The preheat activates bumps 114, as well as conductive layers 112 and 122.

In FIG. 7c, electrical components 220a-220c are aligned with and brought into contact with surface 126 of substrate 120, represented as bonding assembly 219. The electrical and mechanical bonding process of bumps 114 to conductive layers 112 and 122 utilizes potentially three simultaneous operations. Thermal-compression block 132 applies heat and pressure to electrical components 220a-220c to heat and compress bumps 114, represented by indicator arrow 136. Thermal block 134 applies heat to interconnect substrate 120 to provide additional heat, represented by indicator arrow 138.

It is important the heat and pressure remain uniform, with minimal stress, across bumps 114 to maximize or at least enhance the molecular and atomic bonding between bumps 114 and conductive layers 112 and 122. Toward that end, bonding assembly 219 is disposed within microwave source 140 to transmit VFM signal 142 to bumps 114 and conductive layers 112 and 122. FIG. 7d shows further detail of heat-pressure indicator 136, heat indicator 138, and VFM signals 142 around bumps 114 and conductive layers 112 and 122, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 7e shows electrical components 220a-220c bonded to interconnect substrate 120 with bumps 114 electrically and mechanically connected between conductive layers 112 and 122 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution. FIG. 7f shows electrical components 220a-220c and interconnect substrate 120, outside bonding assembly 219, with bumps 114 electrically and mechanically connected between conductive layers 112 and 122.

Electrical components 220a-220c and interconnect substrate 120 are singulated using a saw blade or laser cutting tool 221 into individual semiconductor packages 222. FIG. 7g shows semiconductor package 222 having improved interconnect bonding with bumps 114 electrically and mechanically connected between conductive layers 112 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background.

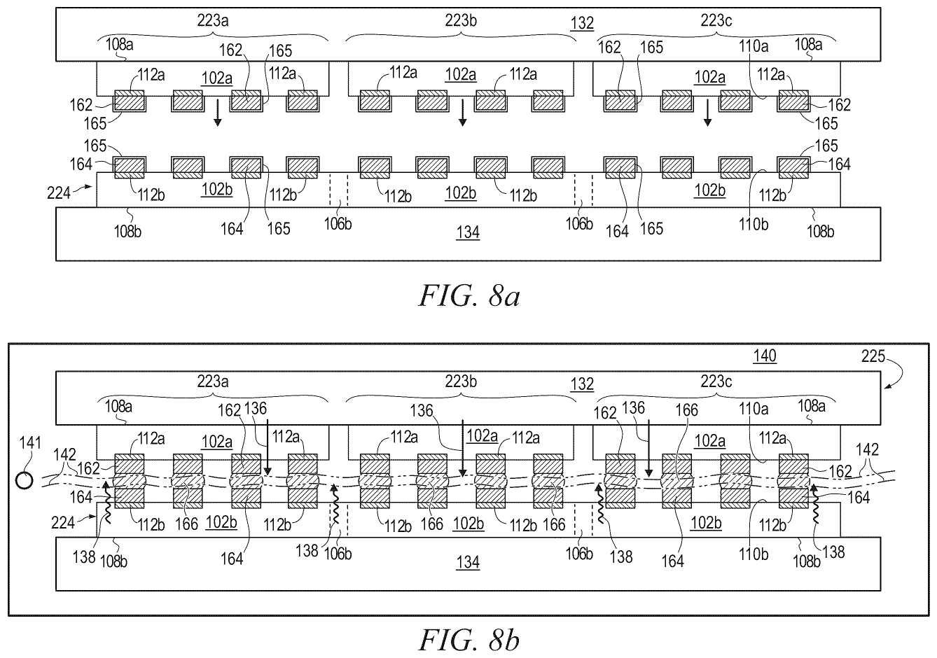

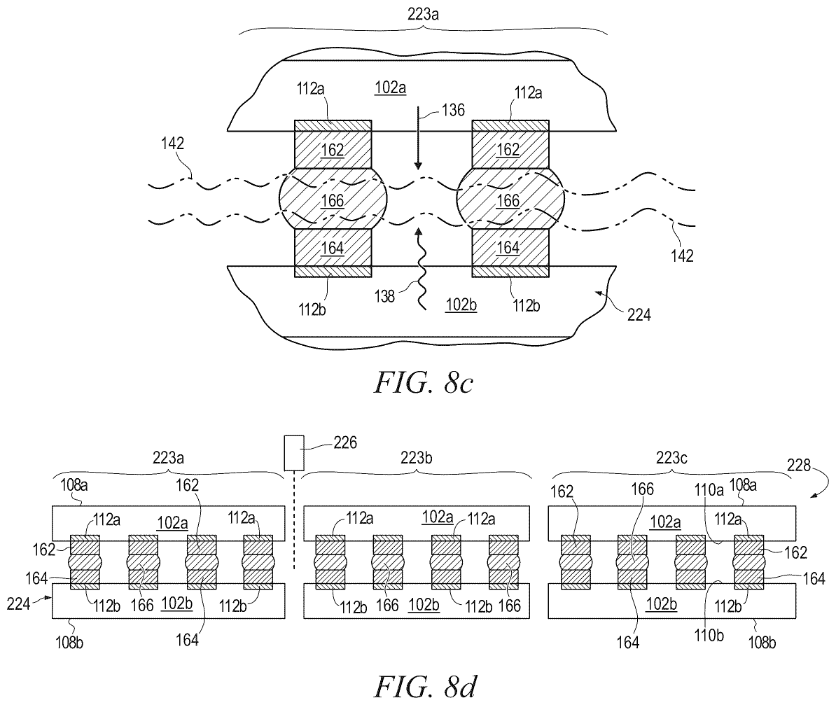

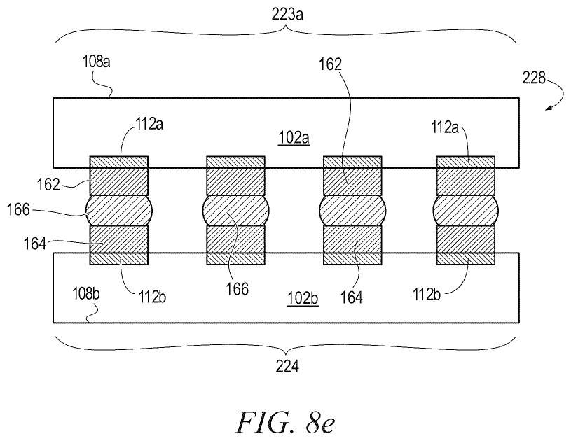

In another embodiment, a plurality of electrical components 223a-223c is disposed over semiconductor wafer 224, as shown in FIG. 8a. In one embodiment, electrical components 223a-223c can be made similar to semiconductor die 104 from FIG. 1e. Alternatively, electrical components 223a-223c can include other semiconductor die, semiconductor packages, surface mount devices, discrete electrical devices, interconnect structures, or IPDs. Semiconductor wafer 224 is made similar to semiconductor wafer 100. As referenced herein, any one of electrical components 223a-223c can be a first substrate and semiconductor wafer 224 can be a second substrate. Also as referenced herein, any one of electrical components 223a-223c can be a first electrical component and semiconductor wafer 224 can be a second electrical component. Conductive pillars 162 and 164 are formed over electrical components 223a-223c and semiconductor wafer 224, respectfully, similar to FIG. 4a. Components having a similar function are assigned the same reference number. A flux material 165 is deposited on conductive pillars 162 and 164. Electrical components 223a-223c are attached to thermal-compression block 132, and semiconductor wafer 224 is attached to thermal block 134. Thermal-compression block 132 applies heat and pressure to electrical components 223a-223c. Thermal block 134 applies heat to semiconductor wafer 224. Electrical components 223a-223c and semiconductor wafer 224 are preheated by thermal-compression block 132 and thermal block 134, respectively.

In FIG. 8b, conductive pillars 162 are aligned with and brought into contact with conductive pillars 164 and intermediate bump material 166, represented as bonding assembly 225. The electrical and mechanical bonding process of bumps 166 to conductive pillars 162 and 164 utilizes potentially three simultaneous operations. Thermal-compression block 132 applies heat and pressure to electrical components 223a-223c to heat and compress bumps 166, represented by indicator arrow 136. Thermal block 134 applies heat to semiconductor wafer 224 to provide additional heat, represented by indicator arrow 138.

It is important the heat and pressure remain uniform, with minimal stress, across bumps 166 to maximize or at least enhance the molecular and atomic bonding between bumps 166 and conductive pillars 162 and 164. Toward that end, bonding assembly 225 is disposed within microwave source 140 to transmit VFM signal 142 to bumps 166 and conductive pillars 162 and 164. FIG. 8c shows further detail of heat-pressure indicator 136, heat indicator 138, and VFM signals 142 around bumps 166 and conductive pillars 162 and 164, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 8d shows electrical components 223a-223c bonded to semiconductor wafer 224 with bumps 166 electrically and mechanically connected between conductive pillars 162 and 164 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution.

Electrical components 223a-223c and semiconductor wafer 224 are singulated using a saw blade or laser cutting tool 226 into individual semiconductor packages 228. FIG. 8e shows semiconductor package 228 having improved interconnect bonding with bumps 166 electrically and mechanically connected between conductive pillars 162 and 164 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background.

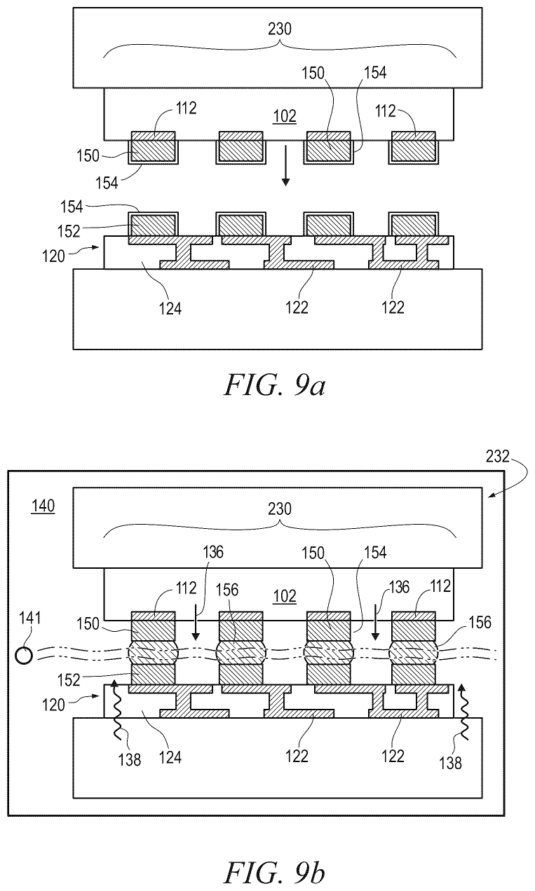

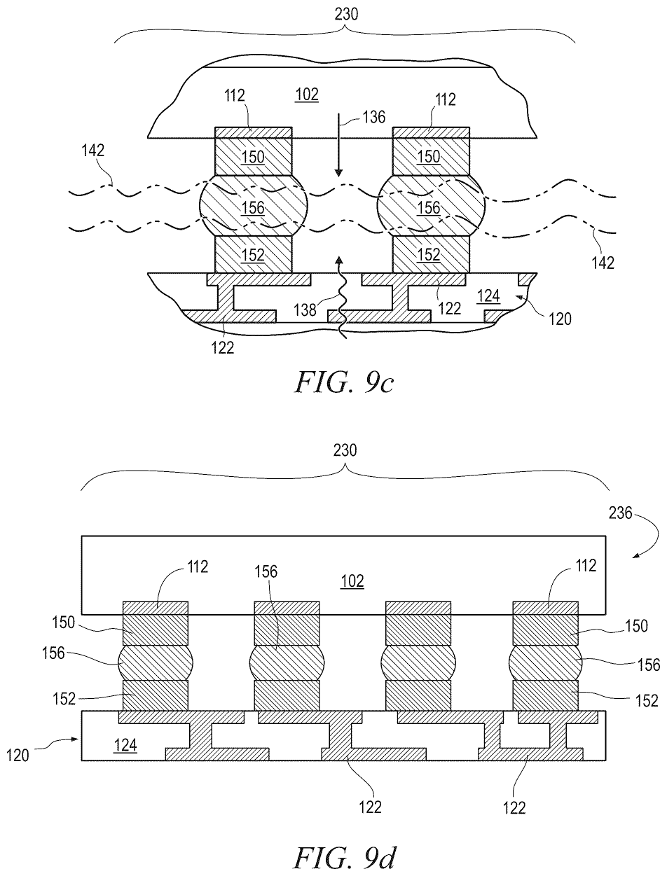

In another embodiment, electrical component 230 is disposed over a die-size portion of interconnect substrate 120, as shown in FIG. 9a. In one embodiment, electrical component 230 can be made similar to semiconductor die 104 from FIG. 1e. Alternatively, electrical component 230 can include other semiconductor die, semiconductor packages, surface mount devices, discrete electrical devices, interconnect structures, or IPDs. As referenced herein, electrical component 230 can be a first substrate and the die-size portion of interconnect substrate 120 can be a second substrate. Also as referenced herein, electrical component 230 can be a first electrical component and the die-size portion of interconnect substrate 120 can be a second electrical component. Conductive pillars 150 and 152 are formed over electrical component 230 and interconnect substrate 120, respectfully, similar to FIG. 3a. A flux material 154 is deposited on conductive pillars 150 and 152. Electrical component 230 is attached to thermal-compression block 132, and the die-size portion of interconnect substrate 120 is attached to thermal block 134. Thermal-compression block 132 applies heat and pressure to electrical component 230. Thermal block 134 applies heat to interconnect substrate 120. Electrical component 230 and interconnect substrate 120 are preheated by thermal-compression block 132 and thermal block 134, respectively.

In FIG. 9b, conductive pillars 150 are aligned with and brought into contact with conductive pillars 152 and intermediate bump material 156, represented as bonding assembly 232. The electrical and mechanical bonding process of bumps 156 to conductive pillars 150 and 152 utilizes potentially three simultaneous operations. Thermal-compression block 132 applies heat and pressure to electrical component 230 to heat and compress bumps 156, represented by indicator arrow 136. Thermal block 134 applies heat to interconnect substrate 120 to provide additional heat, represented by indicator arrow 138.

It is important the heat and pressure remain uniform, with minimal stress, across bumps 156 to maximize or at least enhance the molecular and atomic bonding between bumps 156 and conductive pillars 150 and 152. Toward that end, bonding assembly 232 is disposed within microwave source 140 to transmit VFM signal 142 to bumps 156 and conductive pillars 150 and 152. FIG. 9c shows further detail of heat-pressure indicator 136, heat indicator 138, and VFM signals 142 around bumps 156 and conductive pillars 150 and 152, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 9d shows electrical component 230 bonded to the die-size portion of interconnect substrate 120 with bumps 156 electrically and mechanically connected between conductive pillars 150 and 152, as semiconductor package 236, using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution.

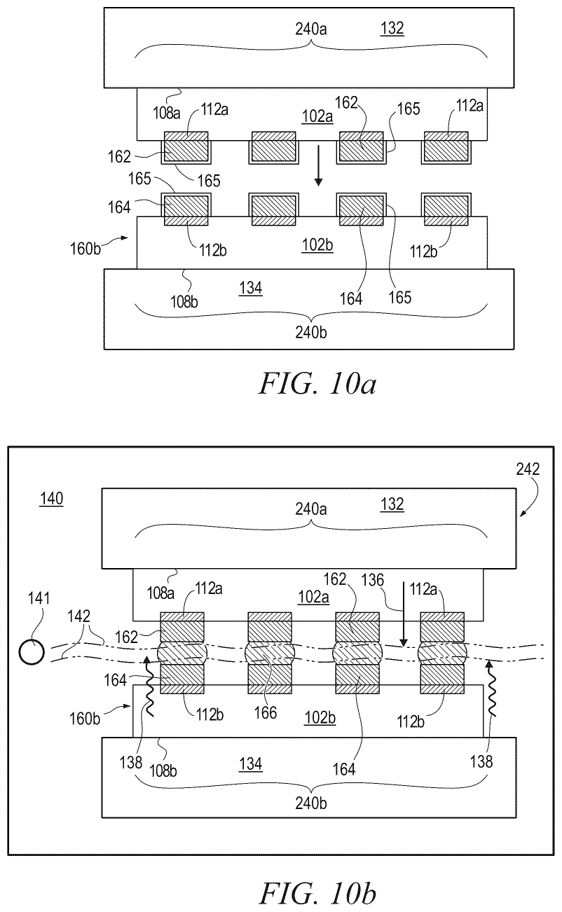

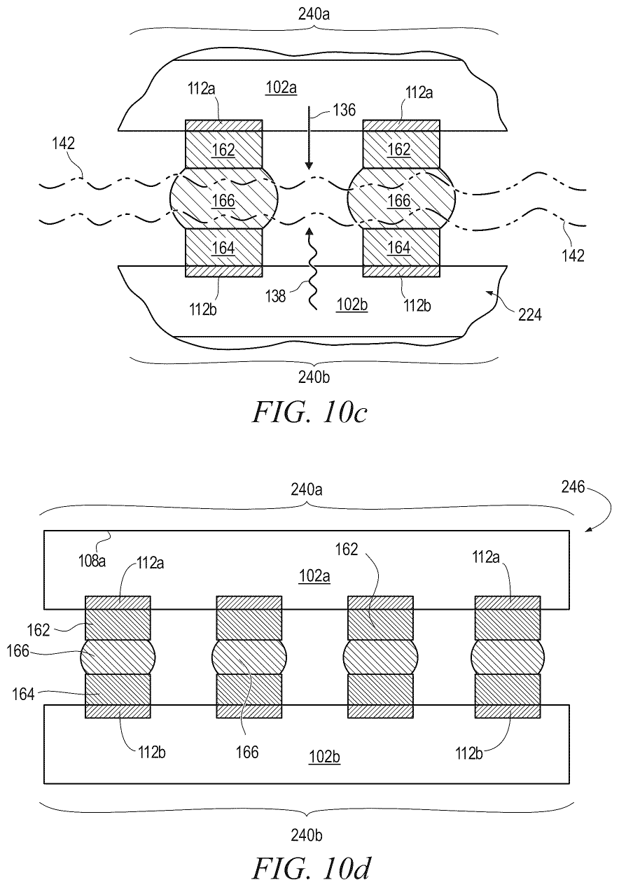

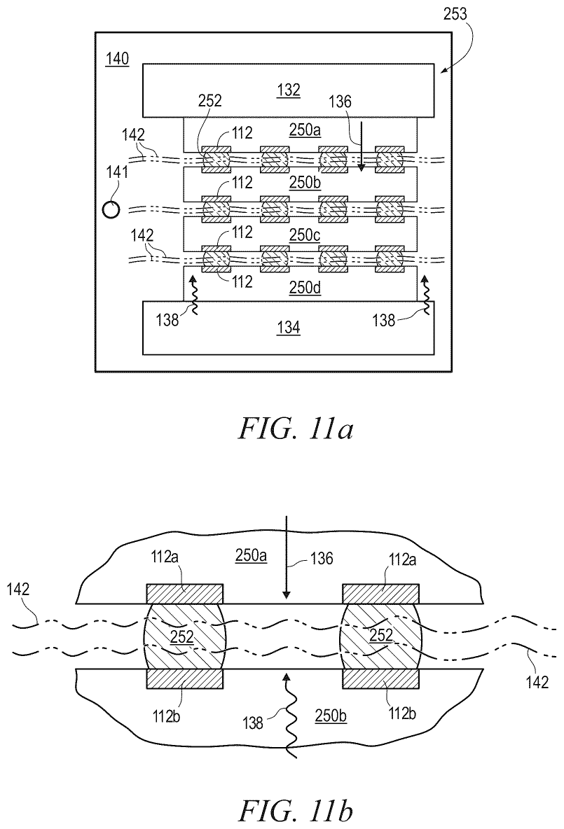

In another embodiment, electrical component 240a is disposed over electrical component 240b, as shown in FIG. 10a. In one embodiment, electrical components 240a and 240b can be made similar to semiconductor die 104 from FIG. 1e. Alternatively, electrical components 240a and 240b can include other semiconductor die, semiconductor packages, surface mount devices, discrete electrical devices, interconnect structures, or IPDs. As referenced herein, electrical component 240a can be a first electrical component and electrical component 240b can be a second electrical component. Also as referenced herein, electrical component 240a can be a first substrate and electrical component 240b can be a second substrate. Conductive pillars 162 and 164 are formed over electrical component 240a and electrical component 240b, respectfully, similar to FIG. 4a. A flux material 165 is deposited on conductive pillars 162 and 164. Electrical component 240a is attached to thermal-compression block 132, and electrical component 240b is attached to thermal block 134. Thermal-compression block 132 applies heat and pressure to electrical component 240a. Thermal block 134 applies heat to electrical component 240b. Electrical components 240a and 240b are preheated by thermal-compression block 132 and thermal block 134, respectively.

In FIG. 10b, conductive pillars 162 are aligned with and brought into contact with conductive pillars 164 and intermediate bump material 166, represented as bonding assembly 242. The electrical and mechanical bonding process of bumps 166 to conductive pillars 162 and 164 utilizes potentially three simultaneous operations. Thermal-compression block 132 applies heat and pressure to electrical component 240a to heat and compress bumps 166, represented by indicator arrow 136. Thermal block 134 applies heat to electrical component 240b to provide additional heat, represented by indicator arrow 138.

It is important the heat and pressure remain uniform, with minimal stress, across bumps 166 to maximize or at least enhance the molecular and atomic bonding between bumps 166 and conductive pillars 162 and 164. Toward that end, bonding assembly 242 is disposed within microwave source 140 to transmit VFM signal 142 to bumps 166 and conductive pillars 162 and 164. FIG. 10c shows further detail of heat-pressure indicator 136, heat indicator 138, and VFM signals 142 around bumps 166 and conductive pillars 162 and 164, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 10d shows electrical component 240a bonded to electrical component 240b with bumps 166 electrically and mechanically connected between conductive pillars 162 and 164, as semiconductor package 246, using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution.

In another embodiment, a plurality of electrical components 250a-250d are stacked, as shown in FIG. 11a. In one embodiment, electrical components 250a-250d can be made similar to semiconductor die 104 from FIG. 1e. Alternatively, electrical components 250a-250d can include other semiconductor die, semiconductor packages, surface mount devices, discrete electrical devices, interconnect structures, or IPDs. As referenced herein, one of electrical components 250a-250d can be a first substrate and one of electrical components 250a-250d can be a second substrate. Also as referenced herein, one of electrical components 250a-250d can be a first electrical component and one of electrical components 250a-250d can be a second electrical component. A flux material is deposited on conductive layers 112, similar to FIGS. 2b-2c. Electrical component 250a is attached to thermal-compression block 132, and electrical component 250d is attached to thermal block 134. Thermal-compression block 132 applies heat and pressure to electrical components 250a-250d. Thermal block 134 applies heat to electrical components 250a-250d. Electrical components 250a-250d are preheated by thermal-compression block 132 and thermal block 134, respectively.

In FIG. 11b, electrical components 250a-250d are aligned with and brought into contact with intermediate bump material 252, represented as bonding assembly 253. The electrical and mechanical bonding process of bumps 252 to conductive layers 112 utilizes potentially three simultaneous operations. Thermal-compression block 132 applies heat and pressure to electrical components 250a-250d to heat and compress bumps 252, represented by indicator arrow 136. Thermal block 134 applies heat to electrical components 250a-250d to provide additional heat, represented by indicator arrow 138.

It is important the heat and pressure remain uniform, with minimal stress, across bumps 252 to maximize or at least enhance the molecular and atomic bonding between bumps 166 and conductive pillars 162 and 164. Toward that end, bonding assembly 253 is disposed within microwave source 140 to transmit VFM signal 142 to bumps 252 and conductive layers 112. FIG. 11b shows further detail of heat-pressure indicator 136, heat indicator 138, and VFM signals 142 around bumps 252 and conductive layers 112, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 11c shows electrical component 250a-250d bonded together with bumps 252 electrically and mechanically connected between conductive layers 112 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution.

An encapsulant or molding compound 254 is deposited over and around stacked electrical components 250a-25d using a paste printing, compressive molding, transfer molding, liquid encapsulant molding, vacuum lamination, spin coating, or other suitable applicator. Encapsulant 254 can be polymer composite material, such as epoxy resin with filler, epoxy acrylate with filler, or polymer with proper filler. Encapsulant 254 is non-conductive, provides structural support, and environmentally protects the semiconductor device from external elements and contaminants.

An electrically conductive bump material is deposited over conductive layer 112 of electrical component 250d using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 258. In one embodiment, bump 258 is formed over a UBM having a wetting layer, barrier layer, and adhesive layer. Bump 258 can also be compression bonded or thermocompression bonded to conductive layer 112. Bump 258 represents one type of interconnect structure that can be formed over conductive layer 112. The interconnect structure can also use bond wires, conductive paste, stud bump, micro bump, or other electrical interconnect.

The combination of stacked electrical components 250a-250d with encapsulant 254 and bumps 258 represent semiconductor package 260. Semiconductor package 260 is particularly useful for HBM. Stacked electrical components 250a-250d have improved interconnect bonding with bumps 252 electrically and mechanically connected between conductive layers 112 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background.

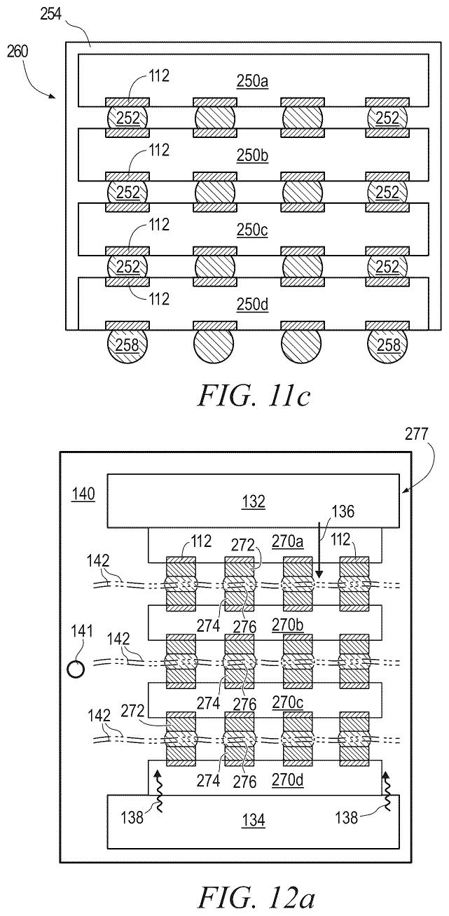

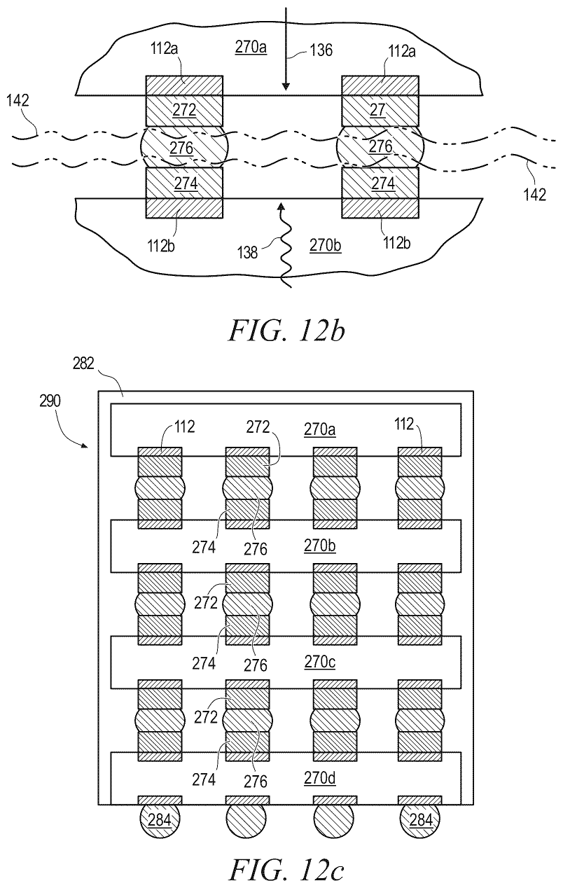

In another embodiment, a plurality of electrical components 270a-270d are stacked, as shown in FIG. 12a. In one embodiment, electrical components 270a-270d can be made similar to semiconductor die 104 from FIG. 1e. Alternatively, electrical components 270a-270d can include other semiconductor die, semiconductor packages, surface mount devices, discrete electrical devices, interconnect structures, or IPDs. As referenced herein, one of electrical components 270a-270d can be a first substrate and one of electrical components 270a-270d can be a second substrate. Also as referenced herein, one of electrical components 270a-270d can be a first electrical component and one of electrical components 270a-270d can be a second electrical component. Conductive pillars 272 and 274 are formed over electrical components 270a-270d, and a flux material is deposited on the conductive pillars, similar to FIG. 4a. Electrical component 270a is attached to thermal-compression block 132, and electrical component 270d is attached to thermal block 134. Thermal-compression block 132 applies heat and pressure to electrical components 270a-270d. Thermal block 134 applies heat to electrical components 270a-270d. Electrical components 270a-270d are preheated by thermal-compression block 132 and thermal block 134.

Conductive pillars 272 are aligned with and brought into contact with conductive pillars 274 and intermediate bump material 276, represented as bonding assembly 277. The electrical and mechanical bonding process of bumps 276 to conductive pillars 272 and 274 utilizes potentially three simultaneous operations. Thermal-compression block 132 applies heat and pressure to electrical components 270a-270d to heat and compress bumps 276, represented by indicator arrow 136. Thermal block 134 applies heat to electrical components 270a-270d to provide additional heat, represented by indicator arrow 138.

It is important the heat and pressure remain uniform, with minimal stress, across bumps 276 to maximize or at least enhance the molecular and atomic bonding between bumps 276 and conductive pillars 272 and 274. Toward that end, bonding assembly 277 is disposed within microwave source 140 to transmit VFM signal 142 to bumps 276 and conductive pillars 272 and 274. FIG. 12b shows further detail of heat-pressure indicator 136, heat indicator 138, and VFM signals 142 around bumps 276 and conductive pillars 272 and 274, following the discussion of FIGS. 2e-2f.

VFM signals 142 can operate with either heat-pressure indicator 136 or heat indicator 138, or without heat-pressure indicator 136 and without heat indicator 138, as described in FIGS. 2e-2k. In any case, FIG. 12c shows electrical components 270a-270d bonded together with bumps 276 electrically and mechanically connected between conductive pillars 272 and 274 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution.

An encapsulant or molding compound 282 is deposited over and around stacked electrical components 270a-27d using a paste printing, compressive molding, transfer molding, liquid encapsulant molding, vacuum lamination, spin coating, or other suitable applicator. Encapsulant 282 can be polymer composite material, such as epoxy resin with filler, epoxy acrylate with filler, or polymer with proper filler. Encapsulant 282 is non-conductive, provides structural support, and environmentally protects the semiconductor device from external elements and contaminants.

An electrically conductive bump material is deposited over conductive layer 112 of electrical component 270d using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 284. In one embodiment, bump 284 is formed over a UBM having a wetting layer, barrier layer, and adhesive layer. Bump 284 can also be compression bonded or thermocompression bonded to conductive layer 112. Bump 284 represents one type of interconnect structure that can be formed over conductive layer 112. The interconnect structure can also use bond wires, conductive paste, stud bump, micro bump, or other electrical interconnect.

The combination of stacked electrical components 270a-270d with encapsulant 282 and bumps 284 represent semiconductor package 290. Semiconductor package 290 is particularly useful for HBM. Stacked electrical components 270a-270d have improved interconnect bonding with bumps 276 electrically and mechanically connected between conductive pillars 272 and 274 using a combination of thermal-compression block 132, thermal block 134, and microwave source 140, or microwave source 140 with either thermal-compression block 132 or thermal block 134, or microwave source 140 without thermal-compression block 132 and without thermal block 134, to achieve a uniform heat-pressure distribution and avoid tilting, slippage, and warpage noted in the background.

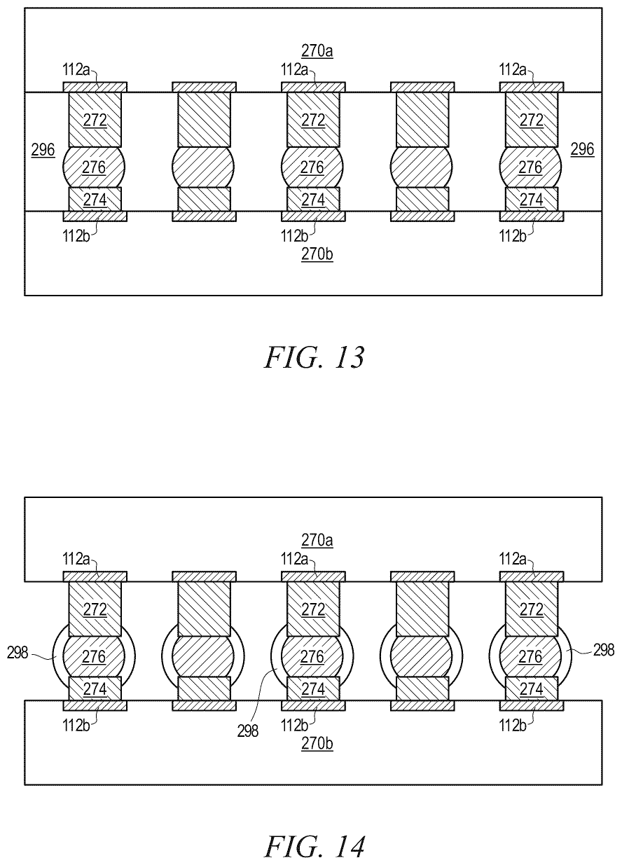

FIG. 13 illustrates an embodiment, similar to FIGS. 12a-12c, with non-conductive film (NCF) 296, including a polar material, deposited around bumps 276 and conductive pillars 272 and 274.

FIG. 14 illustrates an embodiment, similar to FIGS. 12a-12c, with epoxy and flux material 298 deposited around bumps 276 and conductive pillars 272 and 274 to protect the interconnect structure.

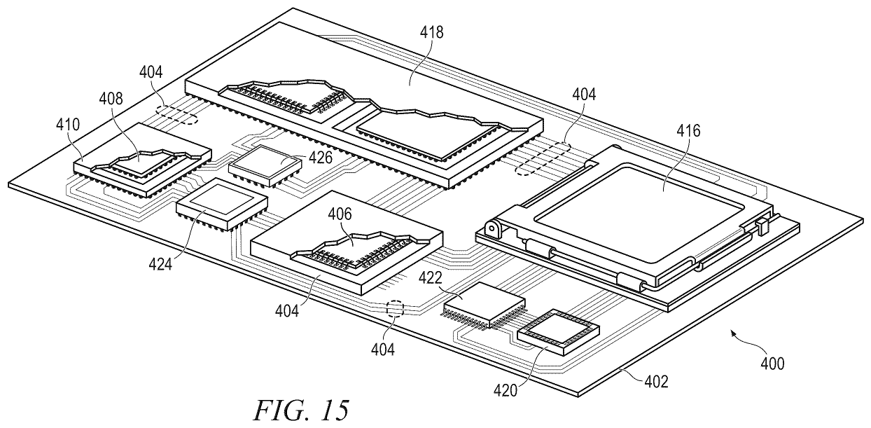

FIG. 15 illustrates electrical device 400 having a chip carrier substrate or PCB 402 with a plurality of semiconductor packages disposed on a surface of PCB 402, including semiconductor packages 148, 159, 168, 180, 210, 222, 228, 236, 246, 260, and 290. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 15, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
providing a second substrate; and
forming an interconnect structure between the first substrate and second substrate using a variable frequency microwave.

2. The method of claim 1, further including applying heat and pressure to the interconnect structure while using the variable frequency microwave.

3. The method of claim 1, further including applying heat or pressure to the interconnect structure while using the variable frequency microwave.

4. The method of claim 1, wherein the interconnect structure includes a bump.

5. The method of claim 1, further including forming a non-conductive film around the interconnect structure between the first substrate and second substrate.

6. The method of claim 1, further including forming an epoxy and flux material around the interconnect structure between the first substrate and second substrate.

7. A method of making a semiconductor device, comprising:
providing a first electrical component;
providing a second electrical component; and
forming an interconnect structure between the first electrical component and second electrical component using a variable frequency microwave.

8. The method of claim 7, wherein the first electrical component includes a semiconductor wafer.

9. The method of claim 7, wherein the first electrical component includes an interconnect substrate.

10. The method of claim 7, further including applying heat or pressure to the interconnect structure while using the variable frequency microwave.

11. The method of claim 7, further including applying heat and pressure to the interconnect structure while using the variable frequency microwave.

12. The method of claim 7, further including forming a non-conductive film around the interconnect structure between the first semiconductor wafer and second semiconductor wafer.

13. The method of claim 7, further including forming an epoxy and flux material around the interconnect structure between the first semiconductor wafer and second semiconductor wafer.

14. A semiconductor device, comprising:
a first substrate;
a second substrate; and
an interconnect structure formed between the first substrate and second substrate with a variable frequency microwave.

15. The semiconductor device of claim 14, further including a thermal-compression block, wherein the first substrate is attached to the thermal-compression block.

16. The semiconductor device of claim 14, further including a thermal block, wherein the second substrate is attached to the thermal block.

17. The semiconductor device of claim 14, wherein the interconnect structure includes a bump.

18. The semiconductor device of claim 14, further including a non-conductive film formed around the interconnect structure between the first substrate and second substrate.

19. The semiconductor device of claim 14, further including an epoxy and flux material formed around the interconnect structure between the first substrate and second substrate.

20. A semiconductor device, comprising:
a first electrical component;
a second electrical component;
an interconnect structure formed between the first electrical component and second electrical component with a variable frequency microwave.

21. The semiconductor device of claim 20, wherein the first electrical component includes a semiconductor substrate.

22. The semiconductor device of claim 20, wherein the first electrical component includes an interconnect substrate.

23. The semiconductor device of claim 20, further including a thermal-compression block, wherein the first electrical component is attached to the thermal-compression block.

24. The semiconductor device of claim 20, further including a thermal block, wherein the second electrical component is attached to the thermal block.

25. The semiconductor device of claim 20, wherein the interconnect structure includes a bump.
